(19) United States
(12) Patent Application Publication
(10) Pub. No.: US 2021/0319955 A1
(43) Pub. Date: Oct. 14, 2021

(54) ULTRATHIN AND FLEXIBLE DEVICES INCLUDING CIRCUIT DIES

(71) Applicant: 3M INNOVATIVE PROPERTIES COMPANY, St. Paul, MN (US)

(72) Inventors: Ankit Mahajan, Cupertino, MN (US); Saagar A. Shah, Minneapolis, MN (US); Mikhail L. Pekurovsky, Bloomington, MN (US); Thomas J. Metzler, St. Paul, MN (US); Kayla C. Niccum, St. Paul, MN (US); Eric A. Vandre, Roseville, MN (US); Aniruddha Upadhye, St. Paul, MN (US); Robert R. Owings, Woodbury, MN (US); Jeremy K. Larsen, Farmington, MN (US); Zohaib Hameed, Woodbury, MN (US)

(21) Appl. No.: 16/949,910

(22) PCT Filed: May 16, 2019
(86) PCT No.: PCT/IB2019/054083

§ 371 Date: Nov. 20, 2020

Related U.S. Application Data
(60) Provisional application No. 62/674,321, filed on May 21, 2018.

(51) Int. Cl. H01G 4/33; H01F 17/00; H01F 41/04; H01C 17/075; H01C 7/00; H01C 1/01; H01C 1/034; H01C 17/00; H01G 2/06; H01G 4/005; H01G 4/224

(52) U.S. Cl. CPC H01G 4/33; H01F 17/0013; H01F 41/042; H01C 17/075; H01C 7/006; H01C 1/01; H01F 2017/006; H01C 17/006; H01G 2/065; H01G 4/005; H01G 4/224; H01F 2017/0073; H01C 1/034

(57) ABSTRACT

Ultrathin and flexible electrical devices including circuit dies such as, for example, a capacitor chip, a resistor chip, and/or an inductor chip, and methods of making and using the same are provided. Circuit dies are attached to a major surface of a flexible substrate having channels Electrically conductive traces are formed in the channels, self-aligned with the circuit dies, and in direct contact with the bottom surface of the circuit dies.

### TECHNICAL FIELD

The present disclosure relates to ultrathin and flexible electrical devices including circuit dies such as passive electronic components (e.g., a capacitor chip, a resistor chip, and/or an inductor chip), and methods of making and using the same.

### BACKGROUND

Integration of solid semiconductor dies with printing techniques combines the computational prowess of semiconductor technology with the high-throughputs and form-factor flexibility of web-based processes. Passive electronic components such as capacitors, resistors and inductors are widely used in various circuits. For example, they serve to tune antennae and circuit frequencies. Thin bare-die passive electronic components (e.g., capacitors) commercially available are relatively thick (e.g., about 100 to 150 micrometers) and are not fabricated from flexible, bendable, or stretchable materials.

### SUMMARY

There is a desire to make ultrathin and flexible passive electronic components to create flexible circuits. Briefly, in one aspect, the present disclosure describes an electrical device including a substrate having a major surface; a circuit die disposed on a registration area of the major surface of the substrate; one or more channels disposed on the major surface of the substrate, extending into the registration area and having a portion underneath a bottom surface of the circuit die; and one or more electrically conductive traces formed in the one or more channels, the electrically conductive traces being in direct contact with the bottom surface of the circuit die.

In another aspect, the present disclosure describes a method of making an electrical device. The method includes providing a substrate having a major surface, the substrate having one or more channels on the major surface; disposing a circuit die on a registration area of the major surface of the substrate, the channels extending into the registration area and having a portion underneath the bottom surface of the circuit die; disposing a conductive liquid into the channels; flowing the conductive liquid in the channels to make direct contact with the bottom surface of the circuit die; and solidifying the conductive liquid to form one or more electrically conductive traces in direct contact with the bottom surface of the circuit die.

Various unexpected results and advantages are obtained in exemplary embodiments of the disclosure. One such advantage of exemplary embodiments of the present disclosure is that passive electronic components are provided in the form of circuit dies to a flexible circuitry where conductive traces, contacts, and components are self-aligned and connected to form ultrathin and flexible electrical circuits.

Various aspects and advantages of exemplary embodiments of the disclosure have been summarized. The above Summary is not intended to describe each illustrated embodiment or every implementation of the present certain exemplary embodiments of the present disclosure. The Drawings and the Detailed Description that follow more particularly exemplify certain preferred embodiments using the principles disclosed herein.

### BRIEF DESCRIPTION OF THE DRAWINGS

The disclosure may be more completely understood in consideration of the following detailed description of various embodiments of the disclosure in connection with the accompanying figures, in which:

FIG. 1A is a top view of a flexible substrate having a channel leading to a registration area, according to one embodiment.

FIG. 1B is a top view of the substrate of FIG. 1A having a curable liquid disposed at the registration area.

FIG. 1C is a top view of the substrate of FIG. 1B having a capacitor chip attached to the registration area via the curable liquid, according to another embodiment.

FIG. 1D is a top view of the substrate of FIG. 1C having a conductive liquid disposed into the channel.

FIG. 1E is a top view of the substrate of FIG. 1D having a dielectric material deposited around the capacitor chip.

FIG. 1F is a top view of the substrate of FIG. 1E having a top conductor disposed on the capacitor chip.

FIG. 2A is a cross-sectional view of the electrical device of FIG. 1F, according to one embodiment.

FIG. 2B is a cross-sectional view of the electrical device of FIG. 1F, according to another embodiment.

FIG. 2C is a cross-sectional view of the electrical device of FIG. 1F, according to another embodiment.

FIG. 3A is a top view of a flexible substrate having two channels leading to a registration area, according to one embodiment.

FIG. 3B is a top view of the substrate of FIG. 3A having a curable liquid disposed at the registration area.

FIG. 3C is a top view of the substrate of FIG. 3B having a resistor chip attached to the registration area via the curable liquid, according to another embodiment.

FIG. 3D is a top view of the substrate of FIG. 1C having a conductive liquid disposed into the channels.

FIG. 4 is a cross-sectional view of the electrical device of FIG. 3D, according to one embodiment.

FIG. 5 is a side perspective view of an inductor chip, according to one embodiment.

FIG. 6A is a top view of a flexible substrate having channels electrically connected to the inductor of FIG. 5 received in a registration area, according to one embodiment.

FIG. 6B is a top view of the substrate of FIG. 6A having a conductive liquid disposed into the channels.

FIG. 6C is a cross-sectional view of the electrical device of FIG. 6B, according to one embodiment.

In the drawings, like reference numerals indicate like elements. While the above-identified drawing, which may not be drawn to scale, sets forth various embodiments of the present disclosure, other embodiments are also contemplated, as noted in the Detailed Description. In all cases, this disclosure describes the presently disclosed disclosure by way of representation of exemplary embodiments and not by express limitations. It should be understood that numerous other modifications and embodiments can be devised by those skilled in the art, which fall within the scope and spirit of this disclosure.

### DETAILED DESCRIPTION

For the following Glossary of defined terms, these definitions shall be applied for the entire application, unless a different definition is provided in the claims or elsewhere in the specification.

### Glossary

Certain terms are used throughout the description and the claims that, while for the most part are well known, may require some explanation. It should be understood that:

The term “circuit die” refers to any suitable substrate on which a given functional circuit is fabricated. In some cases, the circuit die can be a thin and flexible chip made on a polymeric substrate. The flexible circuit die may have a thickness in a range, for example, from about 5 microns to about 1 mm, from about 10 microns to about 500 microns, or from about 20 microns to about 200 microns.

The term “curable material” refers to a material that is viscous when uncured, and solidifies when exposed to heat, UV, or another energy source. The curable material can adhere to the underlying substrate after curing.

The term “conductive liquid” refers to a liquid composition that is flowable in a channel via capillary. The conductive liquid described herein can be solidified to form electrically conductive traces. The conductive liquid may include any suitable electronic material having properties desired for use in forming electrically conductive traces.

The term “adjoining” with reference to a particular layer means joined with or attached to another layer, in a position wherein the two layers are either next to (i.e., adjacent to) and directly contacting each other, or contiguous with each other but not in direct contact (i.e., there are one or more additional layers intervening between the layers).

By using terms of orientation such as “atop”, “on”, “over,” “bottom,” “top,” “up,” “covering”, “uppermost”, “underlying” and the like for the location of various elements in the disclosed coated articles, we refer to the relative position of an element with respect to a horizontally-disposed, upwardly-facing substrate. However, unless otherwise indicated, it is not intended that the substrate or articles should have any particular orientation in space during or after manufacture.

The terms “about” or “approximately” with reference to a numerical value or a shape means +/− five percent of the numerical value or property or characteristic, but expressly includes the exact numerical value. For example, a viscosity of “about” 1 Pa-sec refers to a viscosity from 0.95 to 1.05 Pa-sec, but also expressly includes a viscosity of exactly 1 Pa-sec. Similarly, a perimeter that is “substantially square” is intended to describe a geometric shape having four lateral edges in which each lateral edge has a length which is from 95% to 105% of the length of any other lateral edge, but which also includes a geometric shape in which each lateral edge has exactly the same length.

The term “substantially” with reference to a property or characteristic means that the property or characteristic is exhibited to a greater extent than the opposite of that property or characteristic is exhibited. For example, a substrate that is “substantially” transparent refers to a substrate that transmits more radiation (e.g. visible light) than it fails to transmit (e.g. absorbs and reflects). Thus, a substrate that transmits more than 50% of the visible light incident upon its surface is substantially transparent, but a substrate that transmits 50% or less of the visible light incident upon its surface is not substantially transparent.

As used in this specification and the appended embodiments, the singular forms “a”, “an”, and “the” include plural referents unless the content clearly dictates otherwise. Thus, for example, reference to fine fibers containing “a compound” includes a mixture of two or more compounds. As used in this specification and the appended embodiments, the term “or” is generally employed in its sense including “and/or” unless the content clearly dictates otherwise.

As used in this specification, the recitation of numerical ranges by endpoints includes all numbers subsumed within that range (e.g. 1 to 5 includes 1, 1.5, 2, 2.75, 3, 3.8, 4, and 5).

Unless otherwise indicated, all numbers expressing quantities or ingredients, measurement of properties and so forth used in the specification and embodiments are to be understood as being modified in all instances by the term “about.” Accordingly, unless indicated to the contrary, the numerical parameters set forth in the foregoing specification and attached listing of embodiments can vary depending upon the desired properties sought to be obtained by those skilled in the art utilizing the teachings of the present disclosure. At the very least, and not as an attempt to limit the application of the doctrine of equivalents to the scope of the claimed embodiments, each numerical parameter should at least be construed in light of the number of reported significant digits and by applying ordinary rounding techniques.

Various exemplary embodiments of the disclosure will now be described with particular reference to the Drawings. Exemplary embodiments of the present disclosure may take on various modifications and alterations without departing from the spirit and scope of the disclosure. Accordingly, it is to be understood that the embodiments of the present disclosure are not to be limited to the following described exemplary embodiments, but are to be controlled by the limitations set forth in the claims and any equivalents thereof.

Ultrathin and flexible electrical devices including passive electronic components such as, for example, a capacitor chip, a resistor chip, and/or an inductor chip, and methods of making and using the same are described. The passive electronic components (e.g., capacitors, resistors, and/or inductors) are provided in the form of circuit dies, attached to a major surface of a flexible substrate having channels. Electrically conductive traces are formed in the channels, self-aligned with the circuit dies, and in direct contact with the bottom surface of the circuit dies.

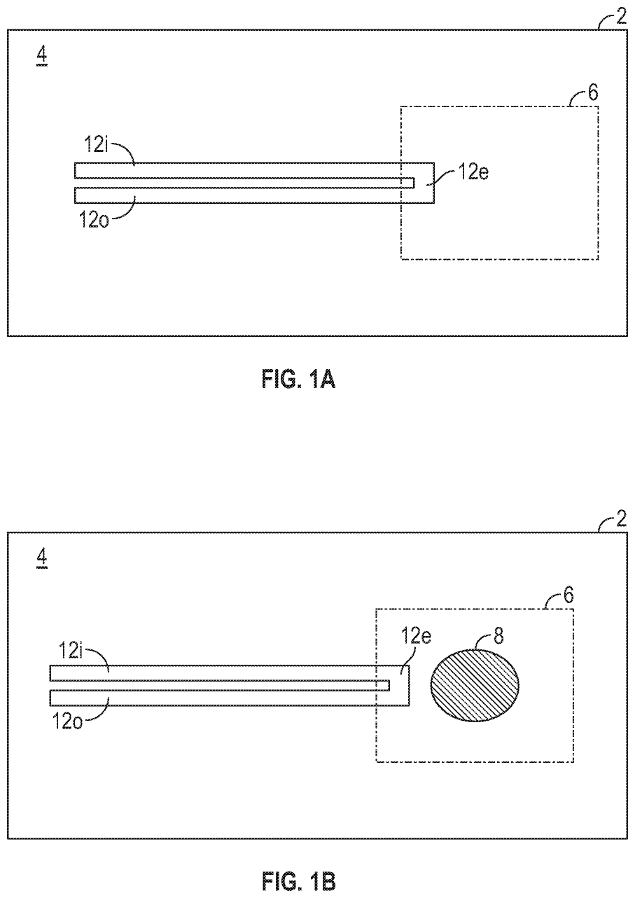

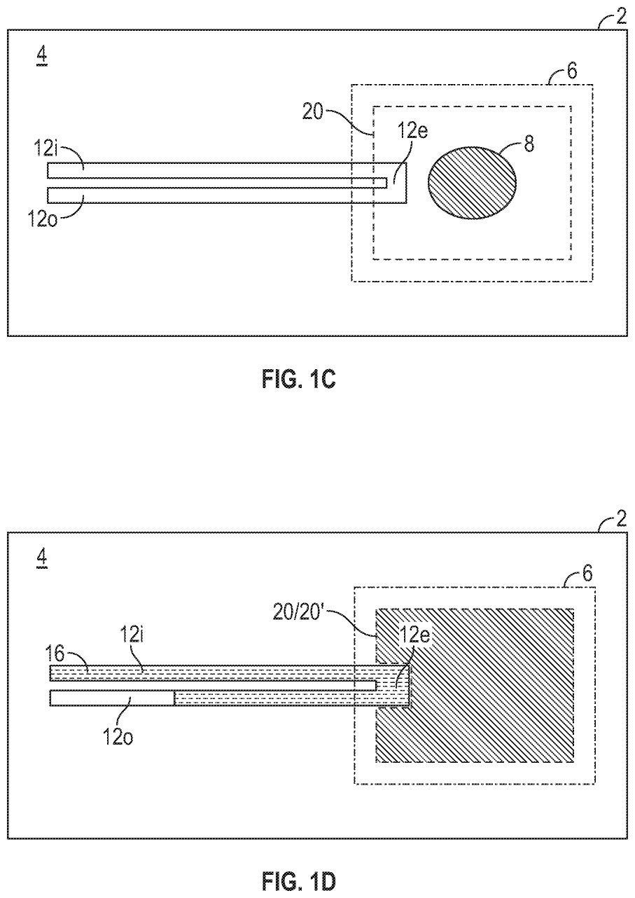

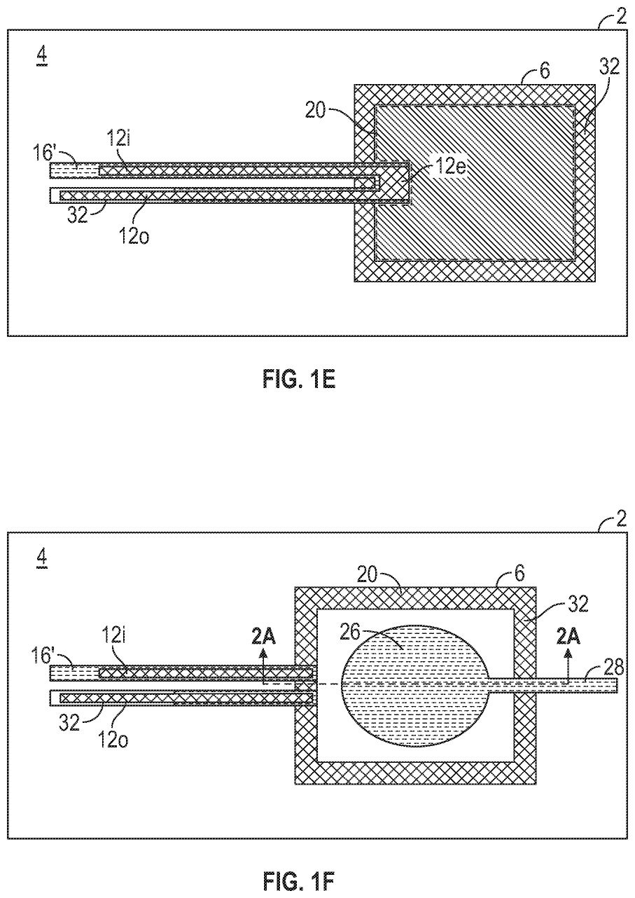

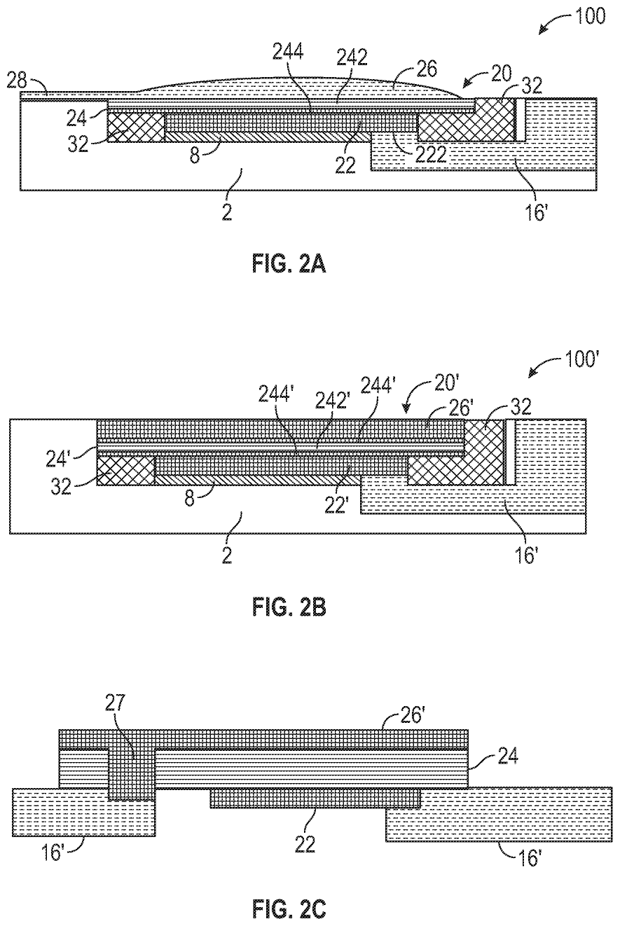

FIGS. 1A-F illustrate a process of forming a flexible electrical device including an ultrathin and flexible capacitor chip, according to one embodiment. FIGS. 2A-B illustrate cross-sectional views of flexible electrical devices 100 and 100′, according to some embodiments. The flexible electrical device is formed on a major surface 4 of a substrate 2 as shown in FIG. 1A. In some embodiments, the substrate 2 can be a flexible substrate, for example, a web of indefinite length polymeric material. The flexible substrate or web may be stretched (e.g., along a machine direction and/or a cross direction) when moving along a web path. The flexible substrate may include, for example, polyethylene terephthalate (PET), polyethylene, polystyrene, polyurethane etc. The processes described herein can be carried out on a roll-to-roll apparatus including one or more rollers to convey the web along the web path. It is to be understood in some embodiments, the substrate 2 or a portion of the substrate 2 may be rigid, made of materials include, for example, bakelite, acrylonitrile butadiene styrene (ABS), cured epoxy systems, etc. The substrate 2 can be made of any suitable materials for forming the features. The substrate 2 may have a thickness of, for example, about 2 mm or less, about 1 mm or less, about 500 microns or less, or about 200 microns or less. The patterned features (e.g., a channel, a pocket, etc.) formed on the major surface 4 may have a minimum dimension of, for example, about 500 microns or less, about 300 microns or less, about 100 microns or less, about 50 microns or less, or about 10 microns or less.

There is a registration area 6 on the major surface which is configured to dispose a circuit die. Patterned features can be formed on the major surface 4 of the substrate 2 adjacent to the registration area 6. In the depicted embodiment, the patterned features include a pairing of inlet channel 12i and outlet channel 12o are formed on the major surface 4 of a substrate 2. The inlet channel 12i and outlet channel 12o are fluidly connected at an inner channel 12e which extends into the registration area 6. It is to be understood that an inner channel formed by fluidly connecting an inlet channel and an outlet channel can have various configurations or shapes such as, for example, a “U” shape, an “L” shape, a straight-line shape, a curved-line shape, etc.

In some embodiments, the patterned features can be formed on the substrate 2 by a micro-replication process. A layer of curable material can be provided onto the substrate. the curable material may include, for example, an adhesive, an acrylate, a urethane, an epoxy, etc. It is to be understood that any suitable curable material can be used, including, for example, structural adhesive, pressure-sensitive adhesive (PSA), epoxy, other types of resins, etc. The layer of adhesive may be applied as an adhesive fluid to cover a localized area on the substrate with any of several convenient coating techniques such as, for example, printing/dispensing such as flexo, inkjet printing, pico-pulse printing, needle printing, micro-pipette printing, etc. A micro-replication stamp can be provided to press against the layer of curable material to create patterned features thereon. Then, the curable material can be cured with, e.g., thermal, UV or e-beam radiation. In other convenient embodiments, the fluid can be dried through solvent evaporation through active or passive drying to form the pattern features (e.g., channels) on the substrate. It is to be understood that the patterned features can be formed on the substrate by any suitable methods such as, for example, embossing, micro-molding, micro-matching, laser etching, 3D printing etc.

In one sample prepared in the present application, the curable material was a layer of optical adhesive commercially available from Norland Products, Inc. (CRANBURY, N.J., USA) under the trade designation NOA-73. A micro-replication stamp was made of polydimethylsiloxane (PDMS), made using a silicone elastomer kit commercially available from Dow Corning, Midland, Mich., under the trade designation Sylgard 184 PDMS. PDMS stamps can be formed, for example, by dispensing an un-crosslinked PDMS polymer into or against a patterned mold followed by curing. It is to be understood that the stamps can be made of any suitable materials such as, for example, silicone, glass, transparent ceramic, transparent polymer, etc. In some embodiments, the stamps can be transparent to allow UV curing of the underlying curable material. In some embodiments, the stamps may be opaque, and the underlying curable material can be thermally cured. In some embodiments, the curable material can be cured from the side of electrical circuitry.

Referring to FIG. 1B, a layer of curable material 8 is provided on the registration area 6. Exemplary curable material may include an adhesive such as, for example, structural adhesives, acrylic adhesives, epoxy adhesive, urethane adhesives, optical adhesives, etc. In some embodiments, the adhering can be performed with, for example, a UV curable polyurethane compound. The layer of adhesive may be applied as an adhesive fluid with any of several convenient coating techniques such as, for example, dispensing, slot coating, curtain coating, notched bar coating, Mayer rod coating, flexographic printing, etc.

A multilayer capacitor chip 20 is attached to the surface of the registration area 6 via the adhesive 8, as shown in FIG. 1C. When the registration area 6 includes a pocket, the multilayer capacitor chip 20 can be attached to the bottom surface of the pocket by the adhesive 8. The adhesive 8 wicks and spreads underneath the capacitor chip 20, adhering the surface of the registration area 6. The adhesive 8 can be pinned to the edges of the channels (e.g., 12e) in the liquid state, leaving the channels intact (see FIG. 1D).

The multilayer capacitor chip 20 is disposed adjacent to the pairing of inlet channel 12i and outlet channel 12o, with the inner channel 12e being underneath a bottom surface of the capacitor chip 20. As shown in FIGS. 2A-B, the multilayer capacitor chip 20 includes a bottom conductor 22 that has a portion 222 exposed to the underneath channels.

In general, the multilayer capacitor chip 20 includes a dielectric layer sandwiched by top and bottom conductors (e.g., a multilayer structure of Au/polymer/Au). The capacitor chip 20 may have a thickness in a range, for example, from about 5 microns to about 1 mm, from about 10 microns to about 500 microns, or from about 20 microns to about 200 microns.

In the embodiment depicted in FIG. 2A, a top conductor 26 is formed on a thin dielectric layer 24 after the capacitor chip 20 is disposed on the substrate 2. In some embodiments, the thin dielectric layer 24 may have a multiplayer structure. The thin dielectric layer 24 of FIG. 2A includes, for example, a thin polymeric layer 242 and a condensed organic layer 244. The thin polymeric layer may include, for example, polyethylene terephthalate (PET), polyethylene, polystyrene, polyurethane etc. The condensed organic layer may include, for example, an acrylate layer. The bottom conductor 22 can be coated on the acrylate layer. The multilayer capacitor chip can include multilayer films described in U.S. Patent Pub. No. 2015/0294793 (Ghosh et al.), which is incorporated herein by reference. In one embodiment, the condensed organic layer may be an acrylate monomer mixture including tricycle decane methanol diacrylate commercially available from Arkema (Paris, France) under the trade designation SR833. In one example, the multilayer capacitor stack was created by laminating a 3-micron sheet of PET with an acrylate coated copper foil. The acrylate was flash evaporated and condensed on the copper and cured with ultraviolet or electron beam radiation. The monomer flow rate, monomer condensation rate, and web speed were chosen to result in a cured polymer layer thickness of, for example, approximately 90 nm to 700 nm.

In the embodiment depicted in FIG. 2B, the multilayer capacitor chip 20′ includes a thin dielectric layer 24′ sandwiched between a bottom conductor 22′ and a top conductor 26′. In some embodiments, the thin dielectric layer 24′ may have a multiplayer structure. For example, the thin dielectric layer 24′ of FIG. 2B includes, for example, a thin polymeric layer 242′ sandwiched by condensed organic layers 244′ on each side. Processes for making the multilayer structures are described in U.S. Patent Pub. No. 2015/0294793 (Ghosh et al.), which is incorporated herein by reference.

Referring to FIG. 1D, when the capacitor chip 20 or 20′ is disposed at the registration area 6, a conductive liquid 16 can be dispensed into the inlet channel 12i. The conductive liquid can be a liquid composition that is flowable in the channels primarily by a capillary force. The conductive liquid may include, for example, a liquid carrier and one or more electronic material, a liquid metal or metal alloy, etc. The conductive liquid described herein can be solidified to leave a continuous layer of electrically conductive material that forms an electrically conductive trace in the channel. Suitable liquid compositions may include, for example, silver ink, silver nanoparticle ink, reactive silver ink, copper ink, conductive polymer inks, liquid metals or alloys (e.g., metals or alloys that melt at low temperatures and solidify at room temperatures), etc.

The conductive liquid can be delivered into the channels by various methods including, for example, ink jet printing, dispensing, micro-injection, etc. In some embodiments, one or more reservoirs can be provided to be adjacent and in fluid communication with an end of the channel The reservoirs can be shaped to provide a convenient receptacle for the dispensed conductive liquid. The conductive liquid 16 can be disposed into the reservoirs by, for example, ink jet printing, dispensing such as piezo dispensing, needle dispensing, screen printing, flexo printing, etc. The conductive liquid 16 can move, by virtue of a capillary pressure, from the reservoirs to the channels. The reservoir may have a depth that is substantially the same as the depth of the channels. The reservoir can have any desirable shapes and dimensions that are suitable for receiving the conductive liquid. In some embodiments, the reservoir may have a diametric dimension in a range, for example, from about 1 micron to about 1.0 mm, from about 5 microns to about 500 microns, or from about 50 microns to about 500 microns.

When the conductive liquid 16 is delivered into the inlet channel 12i, the conductive liquid 16 can be routed, by virtue of a capillary pressure, through the channel from a distal end toward the inner channel 12e. While not wanting to be bounded by theory, it is believed that a number of factors can affect the ability of the conductive liquid to move through the channel via capillarity. Such factors may include, for example, the dimensions of the channels, the viscosity of the conductive liquid, surface energy, surface tension, drying, etc. The factors were discussed in U.S. Pat. No. 9,401,306 (Mahajan et al.), which is incorporated herein by reference.

The conductive liquid travels along the inlet channel 12i through capillary action, wicks under the capacitor chip 20 or 20′ at the inner channel 12e, makes direct contact to the bottom conductor 22 (see also FIGS. 2A-B), and emerges from the outlet channel 12o. The inlet and outlet channels (e.g., 12i and 12o) are fluidly connected at the inner channel 12e, which can help to ensure a continuous liquid flow without trapping air in the inner channels. The conductive liquid is then solidified to create a conductive trace 16′ as shown in FIGS. 2A-C.

In some embodiments, a conductive liquid can flow into the channels (e.g., the inlet and outlet channels 12i and 12o), solidified to form electrically conductive traces therein. For example, the electrically conductive traces can be formed by evaporation of a solvent of liquid conductive ink. During a solidification process, the conductive material can be deposited on the side walls and bottom of the channels, and on the portion 222 of the bottom conductor 22 of the capacitor chip sitting atop the channel, as shown in FIGS. 2A-B. In the process, the conductive material can make a conformal contact with the bottom conductor on the circuit die. The solidification process may leave some void space in the channels underneath the capacitor. The void space can be filled with an encapsulant material to protect the structure. The encapsulant material may include, for example, a dielectric material, a polymeric material, etc. In some embodiments, the encapsulant material can be delivered as a capillary liquid flow to fill the channels. The liquid can flow into the channels, and can then be solidified to reinforce the contact interface formed between the electrically conductive traces and the circuit die. Also, the liquid flow into the gap between the capacitor and the supporting substrate, and can then be solidified to reinforce the contact interface formed between the substrate and the circuit die.

In the embodiment depicted in FIG. 1E, a dielectric material 32 is deposited around the capacitor chip 20 to isolate and protect the bottom conductor 22. The dielectric material 32 is also provided to fill the channels where the conductive trace 16′ is formed. In some embodiments, the dielectric material 32 may include a curing product of a heat curable epoxy. It is to be understood that the dielectric material can include any polymeric dielectric material such as, for example, acrylate, urethane, epoxy, polystyrene, poly(methyl methacrylate) (PMMA), etc., and any additives such as, for example, SiO₂, TiO₂, ZrOₓ, BaSrTiOₓ, etc.

Referring to FIGS. 1F and 2A, a conductive liquid can be deposited on top of the capacitor 20 and solidified to serve as the top conductor 26, according to some embodiments. The top conductor 26 can be formed by any suitable processes such as, for example, ink jet printing, dispensing such as piezo dispensing, needle dispensing, screen printing, flexo printing, etc. A conductive trace 28 can be printed or flowed through channels to electrically connect the top conductor to other components of the electric circuit on the substrate 2.

Referring to FIG. 2C, a via conductor 27 extends through the dielectric layer 24, electrically connecting the top conductor 26 and the conductive trace 16′ in a channel. In the embodiment depicted in FIG. 2C, the capacitor chip can be electrically connected to a flexible electrical device via the conductive trace 16′ in the channels.

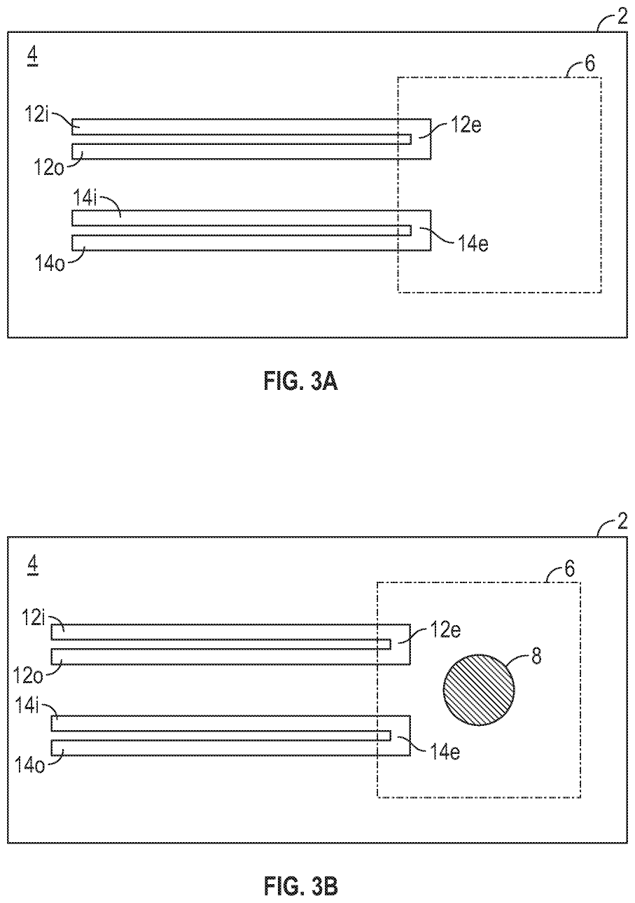

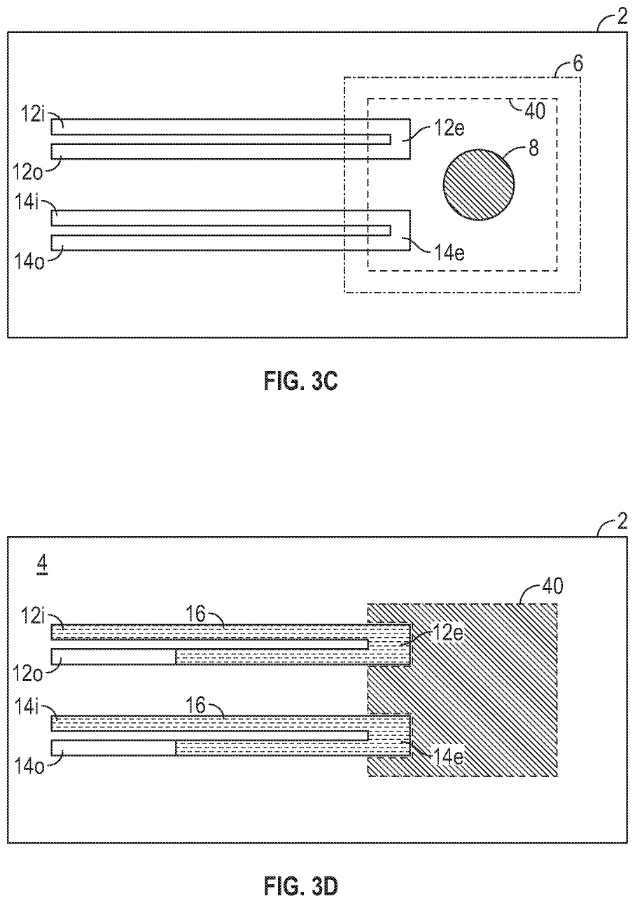

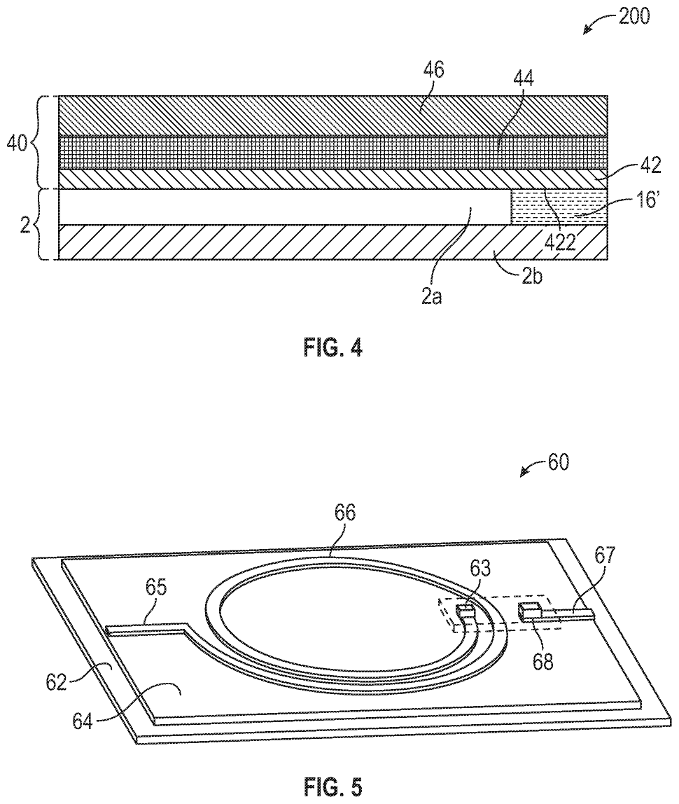

FIGS. 3A-D illustrate a process of forming a flexible electrical device including an ultrathin and flexible resistor chip, according to one embodiment. FIG. 4 illustrate a cross-sectional view of a flexible electrical device 200, according to some embodiments. The flexible electrical device is formed on a major surface 4 of a substrate 2 as shown in FIG. 3A. In some embodiments, the substrate 2 can be a flexible substrate, for example, a web of indefinite length polymeric material. The flexible substrate or web may be stretched (e.g., along a machine direction and/or a cross direction) when moving along a web path. There is a registration area 6 on the major surface which is configured to dispose a circuit die.

In the depicted embodiment, a first pairing of inlet channel 12i and outlet channel 12o and a second pairing of inlet channel 14i and outlet channel 14o are formed on the major surface 4 of the substrate 2. The inlet channel 12i and outlet channel 12o are fluidly connected at one end 12e which extends into the registration area 6. The inlet channel 14i and outlet channel 14o are fluidly connected at one inner channel 14e which also extends into the registration area 6.

In some embodiments, the micro-replicated substrate 2 may be a free-standing, flexible/stretchable substrate. The flexible electrical device 200 formed thereon can be bendable about a radius and stretchable along both planar axes. In one sample prepared in the present application, the micro-replicated substrate was created on a free-standing, micro-replicated, one part, heat curable epoxy without a supporting substrate (e.g., a PET substrate).

In some embodiments, the micro-replicated substrate can be laminated onto another flexible substrate. In one embodiment shown in FIG. 4, a micro-replicated substrate 2a is laminated onto another flexible substrate 2b. In some embodiments, the micro-replicated substrate 2a may include one or more stretchable materials such as, for example, an adhesive, an acrylate, a urethane, an epoxy, etc. In some embodiments, the flexible substrate 2b may include a polymeric film such as, for example, a PET film.

A layer of adhesive 8 is provided on the registration area 6 of the substrate 2, as shown in FIG. 3B. Exemplary adhesives may include structural adhesives, acrylic adhesives, epoxy adhesive, urethane adhesives, optical adhesives, etc. In some embodiments, the adhering can be performed with, for example, a UV curable polyurethane compound. The layer of adhesive may be applied as an adhesive fluid with any of several convenient coating techniques such as, for example, dispensing, slot coating, curtain coating, notched bar coating, Mayer rod coating, flexographic printing, etc. A resistor chip 40 is attached to the surface of the registration area 6 via the adhesive 8, as shown in FIG. 3C. When the registration area 6 includes a pocket, the resistor chip 40 can be attached to the bottom surface of the pocket by the adhesive 8.

The resistor chip 40 is disposed adjacent to the channels 12i, 12o, 14i, and 14o, with the inner channels 12e and 14e each being underneath a bottom surface of the resistor chip 40. The resistor chip 40 includes a bottom resistor layer 42 that has a portion 422 exposed to the underneath channels, as shown in FIG. 4.

In the embodiment depicted in FIG. 4, the resistor chip 40 includes a thin dielectric layer 44 with the bottom resistor layer 42. An overcoat layer 46 is provided on the thin dielectric layer 44 to provide protection. The resistor layer 42 can include one or more materials having suitable conductivities. In some embodiments, the bottom resistor layer 42 can be a thin carbon coating on the bottom surface of the dielectric layer 44. In some embodiments, the bottom resistor layer 42 may be, for example, a PET film with vapor coated metal thereon. The metal may include, for example, Al, Fe, Ag, Au, Ti, Cu, etc. The resistor chip may have a resistance in the range, for example, between about 10 kohm and about 200 kohm. It is to be understood that the bottom resistor layer 42 can include any suitable materials that can provide desired resistance.

In some embodiments, the thin dielectric layer 44 may have a multiplayer structure. The thin dielectric layer may include, for example, multiple thin polymeric layers (e.g., PET, hardcoat, condensed organic thin film, etc.). In one example, the resistor was created by providing a carbon layer onto a PET film via powder rub. The resistor chip described herein may have a thickness, for example, no greater than about 500 microns, no greater than about 200 microns, no greater than about 100 microns, or no greater than about 50 microns. It is to be understood that the thin dielectric layer can be optional and the resistor layer can be a free-standing layer without a backing layer.

Referring to FIG. 3D, when the resistor chip 40 is disposed at the registration area 6, a conductive liquid 16 can be dispensed into the inlet channels 12i and 14i. The conductive liquid 16 can be a liquid composition that is flowable in the channels primarily by a capillary force. The conductive liquid may include, for example, a liquid carrier and one or more electronic material, a liquid metal or metal alloy, etc. The conductive liquid described herein can be solidified to leave a continuous layer of electrically conductive material that forms an electrically conductive trace in the channel. Suitable liquid compositions may include, for example, silver ink, silver nanoparticle ink, reactive silver ink, copper ink, conductive polymer inks, liquid metals or alloys (e.g., metals or alloys that melt at low temperatures and solidify at room temperatures), etc.

The conductive liquid travels along the respective inlet channels 12i and 14i through capillary action, wicks under the resistor chip 40 at the respective ends 12e and 14e, makes direct contact to the bottom resistor layer 44 (see also FIG. 4), and emerges from the respective outlet channels 12o and 14o. The conductive liquid 16 is then solidified to create the conductive trace 16′.

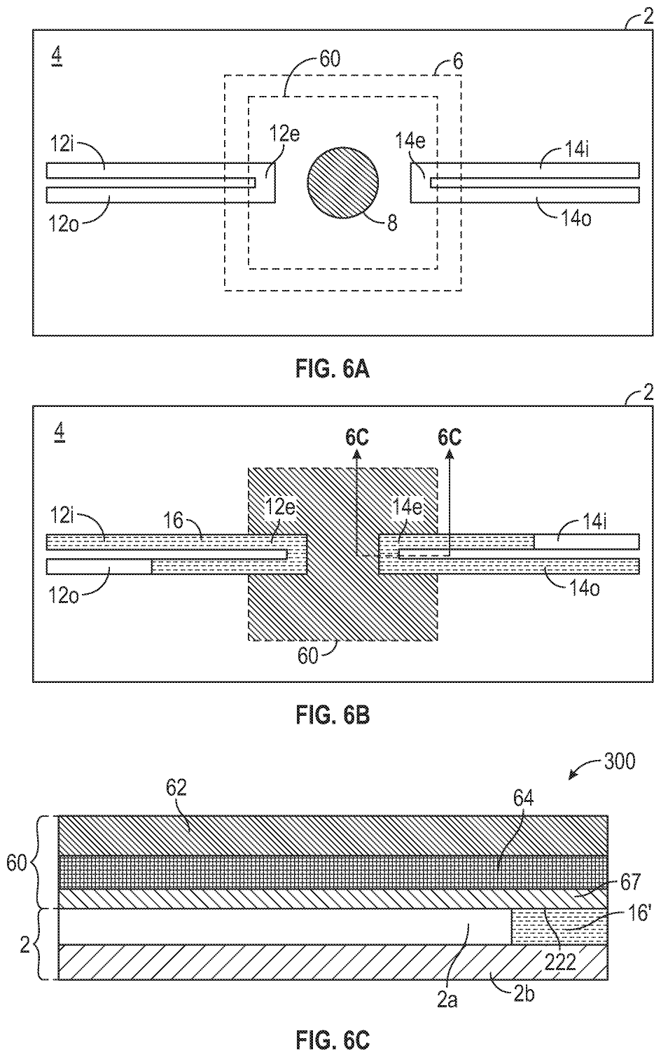

FIGS. 6A-B illustrate a process of forming a flexible electrical device including an inductor chip 60 as shown in FIG. 5. The exemplary inductor chip 60 includes a spiral metal structure 66 pattered onto a flexible insulating substrate 62 which can be, for example, a flexible polymeric substrate. An inside end 63 of the spiral metal structure 66 is connected to an outside contact 67 through an electrical jumper 68. Examples of jumpers and methods of making the jumpers are described in U.S. Patent Application No. 62/651,432 (Goeddel et al.), which is incorporated herein by reference. A thin layer of ferromagnetic material 64 can be deposited on the insulating substrate. To integrate the inductor chip 60 into a flexible electrical device, connects need to be made at the contacts 65 and 67, respectively. FIG. 6C illustrates a cross-sectional view of a flexible electrical device 300 where the inductor chip 60 is received, according to some embodiments.

The flexible electrical device 300 is formed on a major surface 4 of a substrate 2 as shown in FIG. 6A. In some embodiments, the substrate 2 can be a flexible substrate, for example, a web of indefinite length polymeric material. The flexible substrate or web may be stretched (e.g., along a machine direction and/or a cross direction) when moving along a web path. There is a registration area 6 on the major surface which is configured to dispose a circuit die.

Patterned features can be formed on the major surface 4 of the substrate 2, e.g., by a micro-replication process. In the depicted embodiment, a first pairing of inlet channel 12i and outlet channel 12o and a second pairing of inlet channel 14i and outlet channel 14o are formed on the major surface 4 of the substrate 2. The inlet channel 12i and outlet channel 12o are fluidly connected at one end 12e which extends into the registration area 6. The inlet channel 14i and outlet channel 14o are fluidly connected at one inner channel 14e which also extends into the registration area 6. The inner channels 12e and 14e are posited at opposite sides of the registration area 6.

The inductor chip 60 is attached to the surface of the registration area 6 via the adhesive 8, as shown in FIG. 6A. When the registration area 6 includes a pocket, the inductor chip 40 can be attached to the bottom surface of the pocket by the adhesive 8. The inductor chip 60 is disposed adjacent to the channels 12i, 12o, 14i, and 14o, with the inner channels 12e and 14e each being underneath a bottom surface of the inductor chip 60.

In some embodiments, the inductor chip 60 can be positioned to have the contacts 65 and 67 facing the inner channels 12e and 14e, respectively. In some embodiments, the inductor chip 60 may have via conductors such as the via conductor 27 of FIG. 2C that have one end connect to the contacts 65 and 67, respectively. The inductor chip 60 can be positioned with the respective via conductors having the opposite end facing the inner channels 12e and 14e.

Referring to FIGS. 6B-C, when the resistor chip 40 is disposed at the registration area 6, a conductive liquid 16 can be dispensed into the inlet channels 12i and 14i. The conductive liquid 16 travels along the respective inlet channels 12i and 14i through capillary action, wicks under the inductor chip 60 at the respective ends 12e and 14e, makes direct contact to the contacts 65 and 67 (see also FIG. 5), and emerges from the respective outlet channels 12o and 14o. The conductive liquid 16 is then solidified to create the conductive trace 16′.

The operation of the present disclosure will be further described with regard to the following embodiments. These embodiments are offered to further illustrate the various specific and preferred embodiments and techniques. It should be understood, however, that many variations and modifications may be made while remaining within the scope of the present disclosure.

Listing of Exemplary Embodiments

It is to be understood that any one of embodiments 1-10 and 11-21 can be combined.

Embodiment 1 is an electrical device comprising:
a substrate having a major surface;
a circuit die disposed on a registration area of the major surface of the substrate;

one or more channels disposed on the major surface of the substrate, extending into the registration area and having a portion underneath a bottom surface of the circuit die; and

one or more electrically conductive traces formed in the one or more channels, the electrically conductive traces being in direct contact with the bottom surface of the circuit die.

Embodiment 2 is the article of embodiment 1, wherein the channels comprise an inlet channel and an outlet channel that are fluidly connected to form an inner channel, at least a portion of the inner channel being underneath the bottom surface of the circuit die.

Embodiment 3 is the article of embodiment 1 or 2, wherein the circuit die is an electrical capacitor including a thin dielectric layer, and top and bottom electrodes sandwiching the thin dielectric layer.

Embodiment 4 is the article of any one of embodiments 1-3, wherein the circuit die is an electrical resistor including a polymeric substrate with a resistor layer coated on a bottom surface thereof.

Embodiment 5 is the article of any one of embodiments 1-4, wherein the circuit die is an inductor including an insulating substrate and an electrical trace in a spiral pattern.

Embodiment 6 is the article of any one of embodiments 1-5, wherein the registration area comprises a pocket to receive the circuit die.

Embodiment 7 is the article of any one of embodiments 1-6, further comprising an encapsulant material to backfill the channels and protect the circuit die and the electrically conductive traces in direct contact therewith.

Embodiment 8 is the article of any one of embodiments 1-7, wherein the substrate is a flexible substrate including a web of indefinite length polymeric material.

Embodiment 9 is the article of any one of embodiments 1-8, the circuit die is a flexible die having a thickness in a range from about 10 microns to about 500 microns.

Embodiment 10 is a method of making an electrical device, the method comprising:
providing a substrate having a major surface, the substrate having one or more channels on the major surface;
disposing a circuit die on a registration area of the major surface of the substrate, the channels extending into the registration area and having a portion underneath the bottom surface of the circuit die;
disposing a conductive liquid into the channels;
flowing the conductive liquid in the channels to make direct contact with the bottom surface of the circuit die; and
solidifying the conductive liquid to form one or more electrically conductive traces in direct contact with the bottom surface of the circuit die.

Embodiment 11 is the method of embodiment 10, wherein the channels comprise an inlet channel and an outlet channel that are fluidly connected, and the conductive liquid flows into the inlet channel.

Embodiment 12 is the method of embodiment 10 or 11, wherein the circuit die is an electrical capacitor chip including a thin dielectric layer and top and bottom electrodes sandwiching the thin dielectric layer.

Embodiment 13 is the method of embodiment 12, wherein the electrically conductive traces electrically connect to the top and bottom electrode of the capacitor chip.

Embodiment 14 is the method of embodiment 10 or 11, wherein the circuit die is an electrical resistor chip including a polymeric substrate with a resistor layer coated on a bottom surface thereof.

Embodiment 15 is the method of embodiment 14, wherein the electrically conductive traces are in direct contact with the resistor layer of the resistor chip.

Embodiment 16 is the method of embodiment 10 or 11, wherein the circuit die is an inductor chip including an insulating substrate and an electrical trace in a spiral pattern.

Embodiment 17 is the method of embodiment 16, wherein at least one of the electrically conductive traces is in direct contact with the electrical trace of the inductor chip.

Embodiment 18 is the method of any one of embodiments 10-17, wherein the registration area includes a pocket to receive the circuit die.

Embodiment 19 is the method of any one of embodiments 10-18 further comprising backfilling the channels with an encapsulant material.

Embodiment 20 is the method of any one of embodiments 10-19 further comprising surrounding the circuit die with an encapsulant material to protect the circuit die and the electrically conductive traces in direct contact therewith.

Embodiment 21 is the method of any one of embodiments 10-20, wherein the method is carried out on a roll-to-roll apparatus.

Reference throughout this specification to “one embodiment,” “certain embodiments,” “one or more embodiments” or “an embodiment,” whether or not including the term “exemplary” preceding the term “embodiment,” means that a particular feature, structure, material, or characteristic described in connection with the embodiment is included in at least one embodiment of the certain exemplary embodiments of the present disclosure. Thus, the appearances of the phrases such as “in one or more embodiments,” “in certain embodiments,” “in one embodiment” or “in an embodiment” in various places throughout this specification are not necessarily referring to the same embodiment of the certain exemplary embodiments of the present disclosure. Furthermore, the particular features, structures, materials, or characteristics may be combined in any suitable manner in one or more embodiments.

While the specification has described in detail certain exemplary embodiments, it will be appreciated that those skilled in the art, upon attaining an understanding of the foregoing, may readily conceive of alterations to, variations of, and equivalents to these embodiments. Accordingly, it should be understood that this disclosure is not to be unduly limited to the illustrative embodiments set forth hereinabove. In particular, as used herein, the recitation of numerical ranges by endpoints is intended to include all numbers subsumed within that range (e.g., 1 to 5 includes 1, 1.5, 2, 2.75, 3, 3.80, 4, and 5). In addition, all numbers used herein are assumed to be modified by the term “about.” Furthermore, all publications and patents referenced herein are incorporated by reference in their entirety to the same extent as if each individual publication or patent was specifically and individually indicated to be incorporated by reference. Various exemplary embodiments have been described. These and other embodiments are within the scope of the following claims.

1. An electrical device comprising:
a substrate having a major surface;
a circuit die disposed on a registration area of the major surface of the substrate;
one or more channels disposed on the major surface of the substrate, extending into the registration area and having a portion underneath a bottom surface of the circuit die; and
one or more electrically conductive traces formed in the one or more channels, the electrically conductive traces being in direct contact with the bottom surface of the circuit die.

2. The article of claim 1, wherein the channels comprise an inlet channel and an outlet channel that are fluidly connected to form an inner channel, at least a portion of the inner channel being underneath the bottom surface of the circuit die.

3. The article of claim 1, wherein the circuit die is an electrical capacitor chip including a thin dielectric layer, and top and bottom electrodes sandwiching the thin dielectric layer.

4. The article of claim 1, wherein the circuit die is an electrical resistor including a polymeric substrate with a resistor layer coated on a bottom surface thereof.

5. The article of claim 1, wherein the circuit die is an inductor including an insulating substrate and an electrical trace in a spiral pattern.

6. The article of claim 1, wherein the registration area comprises a pocket to receive the circuit die.

7. The article of claim 1, further comprising an encapsulant material to backfill the channels and protect the circuit die and the electrically conductive traces in direct contact therewith.

8. The article of claim 1, wherein the substrate is a flexible substrate including a web of indefinite length polymeric material.

9. The article of claim 1, the circuit die is a flexible die having a thickness in a range from about 10 microns to about 500 microns.

10. A method of making an electrical device, the method comprising:
providing a substrate having a major surface, the substrate having one or more channels on the major surface;
disposing a circuit die on a registration area of the major surface of the substrate, the channels extending into the registration area and having a portion underneath the bottom surface of the circuit die;
disposing a conductive liquid into the channels;
flowing the conductive liquid in the channels to make direct contact with the bottom surface of the circuit die; and
solidifying the conductive liquid to form one or more electrically conductive traces in direct contact with the bottom surface of the circuit die.

11. The method of claim 10, wherein the channels comprise an inlet channel and an outlet channel that are fluidly connected, and the conductive liquid flows into the inlet channel.

12. The method of claim 10, wherein the circuit die is a capacitor chip including a thin dielectric layer and top and bottom electrodes sandwiching the thin dielectric layer.

13. The method of claim 12, wherein the electrically conductive traces electrically connect to the top and bottom electrode of the capacitor chip.

14. The method of claim 10, wherein the circuit die is an electrical resistor chip including a polymeric substrate with a resistor layer coated on a bottom surface thereof.

15. The method of claim 14, wherein the electrically conductive traces are in direct contact with the resistor layer of the resistor.

16. The method of claim 10, wherein the circuit die is an inductor chip including an insulating substrate and an electrical trace in a spiral pattern.

17. The method of claim 16, wherein at least one of the electrically conductive traces is in direct contact with the electrical trace.

18. The article of claim 3, wherein the electrically conductive traces electrically connect to the top and bottom electrode of the capacitor chip.

19. The article of claim 4, wherein the electrically conductive traces are in direct contact with the resistor layer of the resistor.

20. The article of claim 5, wherein at least one of the electrically conductive traces is in direct contact with the electrical trace of the inductor.
